(19) United States
(12) Patent Application Publication
(10) Pub. No.: US 2010/0012300 A1
(43) Pub. Date: Jan. 21, 2010

(54) HEAT UNIFORMING DEVICE FOR ELECTRONIC APPARATUS

(75) Inventors: Seok-Hwan Moon, Daejeon (KR); Gunn Hwang, Seoul (KR)

Correspondence Address: AMPACC Law Group, 3500 188th Street S.W., SUITE 103, Lynnwood, WA, 98037, US

(73) Assignee: ELECTRONICS AND TELECOMMUNICATIONS RESEARCH INSTITUTE, DAEJEON (KR)

(21) Appl. No.: 12/442,110

(22) PCT Filed: Jul. 20, 2007
(86) PCT No.: PCT/KR07/03517

§ 371 Date: Mar. 20, 2009

(51) Int. Cl. F28D 15/04; H05K 7/20

(52) U.S. Cl. 165/104.26; 165/104.33

(57) ABSTRACT

Provided is a heat uniforming device for an electronic apparatus, which improves the flow and circulation of operating fluid through evaporation and condensation using capillary attraction. The heat uniforming device for the electronic apparatus includes: an evaporation unit comprised of a planar first plate including a first multi-channel capillary region for evaporating an externally injected operating fluid due to heat transmitted from a heating source; and a condensation unit comprised of a planar second plate including a second multi-channel capillary region for condensing vapor supplied from the evaporation unit and a return region having a fluid path that communicates with all channels of the second multi-channel capillary region.

### TECHNICAL FIELD

The present invention relates to a heat uniforming device, and more particularly, to a heat uniforming device for an electronic apparatus, which can reduce the flow resistance of heat generated in a specific position of the electronic apparatus.

### BACKGROUND ART

Due to an improvement in the performance of personal computers (PCs) and an increase in the integration density of packages, the dissipation of heat generated by electronic elements, such as a central processing unit (CPU), has become an important issue. As leading-edge processing technology used for CPUs for PCs has also been applied to other electronic apparatuses, the emission of heat has become problematic in a wide range of electronic apparatuses. For example, as portable phones that need to be designed at a higher density than notebook computers become more highly efficient at the current development speed, the problem of heat may become more serious.

The latest developments involving portable phones are being directed to data services centering on color displays, multimedia, video on demand (VOD), video phones, and mobile games. Thus, the number of processes that must be performed in systems is on the increase. Therefore, it is expected that the amount of heat generated by the systems will continue to increase. In order to ensure the safety of portable phones, it is imperative to develop a technique of dissipating heat in the systems. Also, the portable phones need to be lightweight and downscaled to improve portability. Considering these aspects, it is necessary to develop a heat uniforming device along with a heat transfer device in order to efficiently process heat generated by electronic apparatuses.

A heating portion of an electronic apparatus exists as a hot spot with a small area. However, it is difficult to efficiently dissipate heat by attaching to the electronic apparatus a heat sink for dissipating heat and a cooling device for transferring heat. Therefore, it is required to install a heat uniforming device in the electronic apparatus to reduce heat flow resistance of heat when the heating area of the hot spot suddenly increases to a large area.

Conventionally, a solid material having high thermal conductivity has been widely used to form heat uniforming devices. In this case, however, a temperature difference between a hot junction and a cold junction greatly widens due to the limits of thermal performance. Recently, a technique of utilizing a solid material having a high coefficient of thermal conductivity to form a thermal uniforming device has been proposed, but there is still a specific limit in improving thermal performance.

Furthermore, a heat-pipe-type thermal uniforming device has been conventionally considered. Although this heat-pipe-type thermal uniforming device has high thermal performance, it is difficult to install the heat-pipe-type thermal uniforming device in a very narrow space like a narrow electronic package. When the heat-pipe-type thermal uniforming device is compressed and installed in a narrow space, thermal performance notably deteriorates.

### DISCLOSURE OF INVENTION

### Technical Problem

The present invention provides a heat uniforming device for an electronic apparatus, which is structurally simple and easy to manufacture and may have a thin structure with various sizes so that the heat uniforming device can be easily installed in a narrow space and efficiently dissipate and make uniform heat flow due to smooth flow of an operating fluid.

### Technical Solution

According to an aspect of the present invention, there is provided a heat uniforming device for an electronic apparatus including an evaporation unit and a condensation unit. The evaporation unit is comprised of a planar first plate including a first multi-channel capillary region for evaporating an externally injected operating fluid due to heat transmitted from a heating source. The condensation unit is comprised of a planar second plate including a second multi-channel capillary region for condensing vapor supplied from the evaporation unit and a return region having a fluid path that communicates with all channels of the second multi-channel capillary region.

The heat uniforming device for the electronic apparatus may further include a connection unit comprised of a third plate, which is interposed between the evaporation unit and the condensation unit. The connection unit may include a first hole, which communicates with the first multi-channel capillary region, and a second hole, which communicates with the fluid path of the return region. The first hole may form a first flow path through which the vapor flows from the evaporation unit to the condensation unit, and the second hole may form a second flow path through which a fluid returns from the condensation unit to the evaporation unit.

In some embodiments of the present invention, the first multi-channel capillary region may include a plurality of grooves. For example, the grooves may include a plurality of first grooves formed parallel to one another in a predetermined first d irection. Alternatively, the grooves may include a plurality of first grooves formed parallel to one another in a predetermined first direction and a plurality of second grooves formed parallel to one another in a second direction different from the first direction and connected to the first grooves, and the first and second grooves may form a mesh shape. In this case, the first grooves may be at right angles to the second grooves.

The first multi-channel capillary region may include at least one stepped portion disposed on a top surface of the first multi-channel capillary region. In this case, the depth of the grooves may be variable in a lengthwise direction of the grooves.

In other embodiments of the present invention, the first multi-channel capillary region may include at least one fold of screen mesh inserted into the first plate.

In still other embodiments of the present invention, the second multi-channel capillary region may include a plurality of grooves formed parallel to one another in a predetermined direction. In this case, the fluid path of the return region of the condensation unit may extend in a direction perpendicular to a direction in which the grooves of the second multi-channel capillary region extend.

The first hole of the third plate may be interposed between a first region selected out of the first multi-channel capillary region and the second multi-channel capillary region such that the first region of the first multi-channel capillary region communicates with the second multi-channel capillary region. Also, the second hole of the third plate may be interposed between the fluid path of the return region and a second region selected out of the first multi-channel capillary region such that the fluid path of the return region communicates with the second region of the first multi-channel capillary region.

Furthermore, the first multi-channel capillary region may include a plurality of grooves, which extend parallel to one another such that the grooves communicate with the first and second regions, and the grooves may be deeper in the second region than in the first region.

At least one of the first and second multi-channel capillary regions may include a plurality of grooves that extend parallel to one another. In this case, each of the grooves may have one selected from the group consisting of a semicircular sectional shape, a semi-elliptical sectional shape, and a polygonal sectional shape. The grooves may be spaced a predetermined distance apart from one another. Alternatively, the grooves may be disposed adjacently to one another without leaving any distance from one another.

### ADVANTAGEOUS EFFECTS

In a heat uniforming device for an electronic apparatus according to the present invention, a multi-channel capillary structure is formed in each of plates that constitute an evaporation unit and a condensation unit so that the circulation of operating fluid can be improved by evaporation and condensation of the operating fluid due to enhanced capillary attraction. Also, the backward flow of vapor generated in the evaporation unit can be effectively prevented, and a relatively wide space for the vapor can be ensured. The heat uniforming device for the electronic apparatus according to the present invention can be applied to various fields of electronic apparatuses and, particularly, can be used as a heat dissipation/uniforming device for thin portable electronic apparatuses.

### DESCRIPTION OF DRAWINGS

The above and other features and advantages of the present invention will become more apparent by describing in detail exemplary embodiments thereof with reference to the attached drawings in which:

FIG. 1 is a block diagram of a heat uniforming device for an electronic apparatus according to an embodiment of the present invention;

FIG. 2 is a schematic diagram of a heat uniforming device for an electronic apparatus according to an embodiment of the present invention;

FIG. 3A is an exploded perspective view of an essential part of a heat uniforming device for an electronic apparatus according to an embodiment of the present invention;

FIG. 3B is a cross sectional view taken along a line IIIb-IIIb′ of FIG. 3A, according to an embodiment of the present invention;

FIG. 3C is a cross sectional view taken along a line IIIc-IIIc′ of FIG. 3A, according to an embodiment of the present invention;

FIG. 4 is an exploded perspective view of an essential part of a heat uniforming device for an electronic apparatus according to another embodiment of the present invention;

FIG. 5 is an exploded perspective view of an essential part of a heat uniforming device for an electronic apparatus according to another embodiment of the present invention; and

FIGS. 6A through 6C are perspective views of various examples of an operating fluid injection unit that can be applied to a heat uniforming device for an electronic apparatus according to an embodiment of the present invention.

### BEST MODE

The present invention will now be described more fully hereinafter with reference to the accompanying drawings, in which exemplary embodiments of the invention are shown. In the drawings, the thicknesses of layers and regions are exaggerated for clarity. The same reference numerals are used to denote the same elements in the drawings.

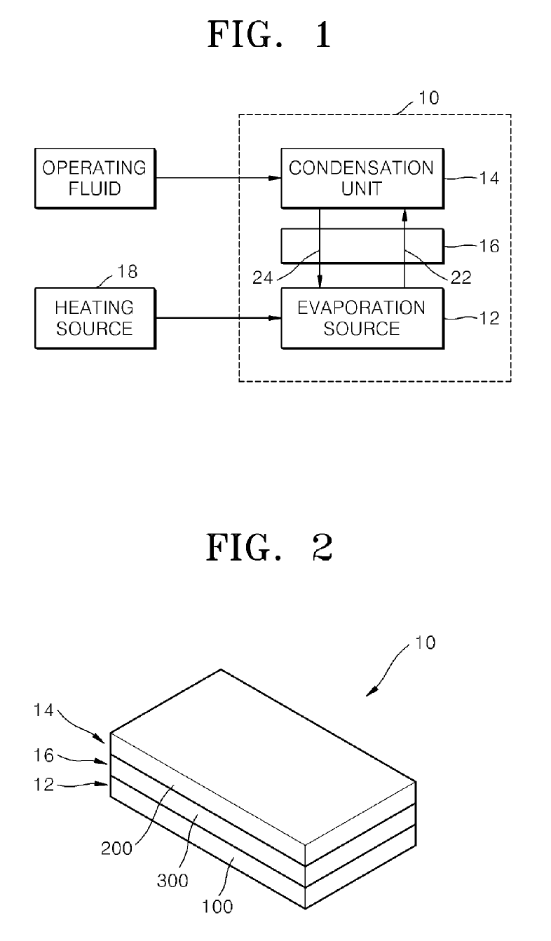

FIG. 1 is a block diagram of a heat uniforming device 10 for an electronic apparatus according to an embodiment of the present invention.

Referring to FIG. 1, the heat uniforming device 10 for the electronic apparatus according to the current embodiment of the present invention includes an evaporation unit 12 and a condensation unit 14. The evaporation unit 12 evaporates an externally injected operating fluid due to heat transmitted to the evaporation unit 12 from a predetermined heating source 18 and supplies vapor evaporated from the operating fluid to the condensation unit 14. The condensation unit 14 condenses the vapor supplied from the evaporation unit 12 and returns the condensed vapor to the evaporation unit 12.

A connection unit 16 may be installed between the evaporation unit 12 and the condensation unit 14 to form fluid paths 22 and 24. The fluid paths 22 and 24 include a first fluid path 22 through which the evaporation unit 12 supplies the evaporated vapor to the condensation unit 14 and a second fluid path 24 through which the condensation unit 14 returns the condensed vapor to the evaporation unit 12.

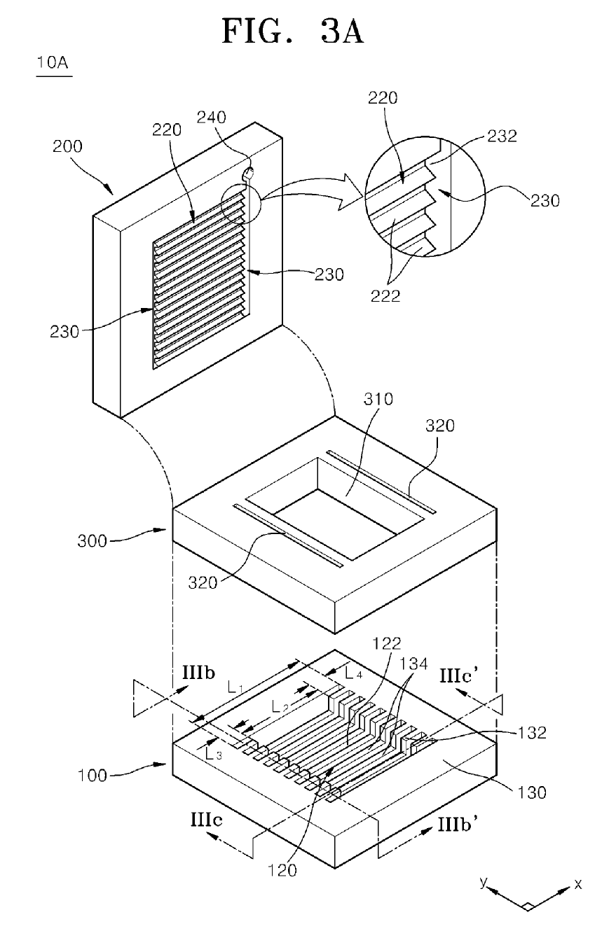

FIG. 2 is a schematic diagram of the heat uniforming device 10 for an electronic apparatus according to an embodiment of the present invention.

Referring to FIG. 2, the evaporation unit 12, the condensation unit 14, and the connection unit 16 of the heat uniforming device 10 for the electronic apparatus according to the current embodiment of the present invention may include a first plate 100, a second plate 200, and a third plate 300, respectively. Each of the first through third plates 100 to 300 may have a planar structure.

In the heat uniforming device 10 for the electronic apparatus as illustrated in FIG. 2, the first plate 100, the third plate 200, and the second plate 100 are stacked in sequence. The first, third, and second plates 100, 300, and 200 are hermetically combined with one another to make airtight an operating fluid path installed therein. Also, an operating fluid injection unit (not shown) having a fluid injection hole may be installed in at least one of the first through third plates 100 to 300 to externally inject an operating fluid into the heat uniforming device 10. A detailed construction of the operating fluid injection unit will be described later.

As described above, the operating fluid is injected through the operating fluid injection unit into the airtight heat uniforming device 10, and heat exchange occurs between the evaporation unit 12 and the condensation unit 14 due to heat transmission caused by phase change.

### MODE FOR INVENTION

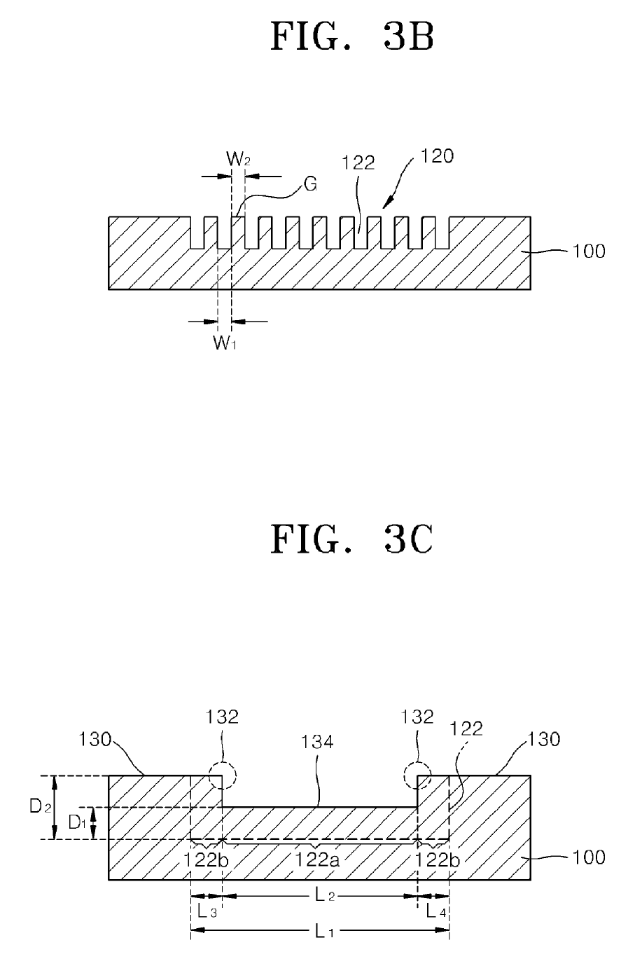

FIG. 3A is an exploded perspective view of an essential part of a heat uniforming device 10A for an electronic apparatus according to an embodiment of the present invention.

Referring to FIG. 3A, the heat uniforming device 10A for the electronic apparatus according to the embodiment of the present invention includes a first plate 100, which constitutes the evaporation unit 12, a second plate 200, which constitutes the condensation unit 14, and a third plate 300, which constitutes the connection unit 16 and is interposed between the first and second plates 100 and 200.

The first plate 100 includes a first multi-channel capillary region 120 having a plurality of channels 122, which functions to evaporate an externally injected operating fluid due to heat transmitted from a heating source 18.

The second plate 200 constituting the condensation unit 14 includes a second multi-channel capillary region 220 and a return region 230. The second multi-channel capillary region 220 includes a plurality of channels 222 and functions to condense vapor supplied from the first plate 100 constituting the evaporation unit 12. The return region 230 includes a groove-type fluid path 232, which communicates with all the channels 222 of the second multi-channel capillary region 220. The return region 230 functions to return the condensed vapor from the second multi-channel capillary region 220 to the first plate 100 constituting the evaporation unit 12.

As illustrated in FIG. 3A, a fluid injection port 240 is formed in the second plate 200 to externally inject the operating fluid. The fluid injection port 240 communicates with the fluid path 232 of the return region 230.

It is illustrated in FIG. 3A that the fluid injection port 240 is formed in the first plate 200. However, the present invention is not limited thereto and the fluid injection port 240 may be formed in a predetermined position of one selected from the group consisting of the first plate 100, the second plate 200, and the third plate 300 if required.

The third plate 300 constituting the connection unit 16 includes a first hole 310, which is formed through the center of the third plate 300, and a plurality of second holes 320, which are formed through the third plate 300 around the first hole 310. FIG. 3A illustrates that the first hole 310 is a rectangular hole and the second holes 320 are two slits formed on both sides of the first hole 310. However, the present invention is not limited thereto and the shapes and numbers of the first and second holes 310 and 320 may be variously selected if required.

The first hole 310 is formed in a position corresponding to the first multi-channel capillary region 120 of the first plate 100 such that the first hole 310 communicates with the first multi-channel capillary region 120 of the first plate 100. The first hole 310 forms a first flow path 22 (FIG. 1) through which vapor flows through the first plate 100 to the second plate 200. Also, the first hole 310 is disposed directly over the first multi-channel capillary region 120 and forms a vapor space unit that is filled with vapor supplied from the first multi-channel capillary region 120.

The second hole 320 communicates with the fluid path 232 formed in the return region 230 of the second plate 200 and forms a second flow path 24 (FIG. 1) through which a fluid returns from the second plate 200 to the first plate 100. As illustrated in FIG. 2A, the second hole 320 may be formed to a size similar to the fluid path 232 in a position corresponding to the fluid path 232 formed in the return region 230 of the second plate 200.

The vapor evaporated in the first plate 100 and the fluid condensed in the second plate 200 may circulate between the first plate 100 and the second plate 200 through the first and second holes 310 and 320, so that heat transmission caused by phase change is attained.

In the first plate 100, the evaporation of the operating fluid occurs in the first multi-channel capillary region 120. The channels 122 formed in the first multi-channel capillary region 120 may be a plurality of grooves, which are formed in the first plate 100 parallel to one another in a predetermined direction, for example, in an x direction of FIG. 3A.

FIG. 3B is a cross sectional view taken along a line IIIb-IIIb′ of FIG. 3A that illustrates a sectional structure of the first multi-channel capillary region 120 including the groove-type channels 122, which is taken along a y direction of FIG. 3A.

Referring to FIG. 3B, the first multi-channel capillary region 120 includes a plurality of groove-type channels 122 formed parallel to one another in the x direction of FIG. 3A. The channels 122 are repetitively formed at fine pitches. Each of the channels 122 may be a groove with a width W of, for example, about 10 to 200□.

FIG. 3B exemplarily illustrates that the groove-type channel 122 has a rectangular sectional shape. However, the present invention is not limited thereto. In some cases, each of the channels 122 may be a groove having a semicircular sectional shape, a semi-elliptical sectional shape, or a polygonal sectional shape. FIGS. 3A and 3B exemplarily illustrate that there is a gap G with a predetermined width W₂ between two adjacent channels 122, and the channels 122 are spaced a distance corresponding to the width W₂ apart from one another and extend parallel to one another. However, the present invention is not limited thereto. For example, when each of the channels 122 is a groove having a semicircular sectional shape, a semi-elliptical sectional shape, or a triangular sectional shape, the channels 122 may extend parallel to one another adjacently to one another such that the width W₂ of the gap G between two adjacent channels 122 is substantially 0. In this case, the first multi-channel capillary region 120 includes a sharp edge between two adjacent to channels 122, thereby greatly enhancing capillary attraction. As a result, the circulation of the operating fluid occurred by evaporation and condensation can be improved.

Referring again to FIG. 3A, at least one stepped portion 132 may be formed on a top surface of the first multi-channel capillary region 120. FIG. 3A illustrates that two stepped portions 132 are formed on the top surface of the first multi-channel capillary region 120.

Due to the stepped portions 132 formed in the first multi-channel capillary region 120, a recess portion 134 is formed in a part of the first multi-channel capillary region 120. The recess portion 134 has a less height than a top surface 130 of an edge of the first plate 100.

FIG. 3C is a cross sectional view taken along a line IIIc-IIIc′ of FIG. 3A that illustrates a sectional structure of the first multi-channel capillary region 120 including the channels 122, which is taken along the x direction of FIG. 3A.

In FIGS. 3A and 3C, reference character “L₁” denotes the total length of the channel 122 formed in the first multi-channel capillary region 120, which is measured in the x direction, and “L₂” denotes the length of a portion of the channel 122 formed in the first multi-channel capillary region 120 corresponding to the recess portion 134.

As illustrated in FIG. 3C, when the stepped portions 132 are formed, the depth of the channel 122 is variable in the lengthwise direction of the channel 122 (i.e., in the x direction of FIG. 3A). Specifically, a first region 122a of the channel 122, which extends along the length L₂ of the recess portion 134, has a relatively small depth D₁, while a second region 122b of the channel 122, which extends by a predetermined distance L₃ or L₄ around the recess portion 134, i.e., along the top surface 130 of the edge of the first plate 100, has a relatively large depth D₂.

FIG. 3A exemplarily illustrates that the channels 122 are formed parallel to one another in one direction in the first multi-channel capillary region 120 of the first plate 100. However, the present invention is not limited thereto. Although not shown in the drawings, the first multi-channel capillary region 120 may include a mesh-shaped groove comprised of a plurality of first grooves and a plurality of second grooves such that a plurality of channels extend in two directions and intersect one another. The first grooves may be formed parallel to one another in a predetermined first direction, and the second grooves may be formed parallel to one another in a second direction different from the first direction and connected to the first grooves. Here, the first direction may be at right angles to the second direction.

A region of the first multi-channel capillary region 120 where the recess portion 134 is located, namely, the first region 122a of FIG. 3C, may be disposed in a position corresponding to the second multi-channel capillary region 220 of the second plate 200. Also, the first hole 310 of the third plate 300 is interposed between the recess portion 134 of the first multi-channel capillary region 220 and the second multi-channel capillary region 220 of the second plate 200 such that the recess portion 134 communicates with the second multi-channel capillary region 220.

Furthermore, the remaining region of the first multi-channel capillary region 120 except the recess portion 134, namely, the second region 122b, may be disposed in a position corresponding to the return region 230 of the second plate 200. Also, the second hole 320 of the third plate 300 is interposed between the second region 122b of the first multi-channel capillary region 120 and the fluid path 232 of the return region 230 of the second plate 200 such that the second region 122b communicates with the fluid path 232.

Referring again to FIG. 3A, the channels 222 formed in the second multi-channel capillary region 220 of the second plate 200 may be a plurality of grooves as exemplarily illustrated in FIG. 3A. When the channels 222 are the grooves, each of the grooves may have a semicircular sectional shape, a semi-elliptical sectional shape, or a polygonal sectional shape as the above-described channel 122 of the first multi-channel capillary region 120. Each of the channels may be a groove with a width of, for example, about 10 to 200□. Also, the fluid path 232 formed in the return region 230 of the second plate 200 may extend in a direction perpendicular to a direction in which the grooves forming the channels 222 extend.

In the heat uniforming device 10A for the electronic apparatus according to the current embodiment of the present invention as described with reference to FIGS. 3A through 3C, the operating fluid is evaporated through the channels 122 formed in the first multi-channel capillary region 120 of the first plate 100 constituting the evaporation unit 12, and vapor evaporated from the operating fluid is condensed through the channels 222 formed in the second multi-channel capillary region 220 of the second plate 200 constituting the condensation unit 14.

The first multi-channel capillary region 120 formed in the first plate 100 includes a plurality of channels 122 to enhance capillary attraction so that the operating fluid can efficiently return from the condensation unit 14 to the evaporation unit 12.

Also, the stepped region 132 is formed on the top surface of the top surface 130 of the first multi-channel capillary region 120 of the first plate 100 so that the second hole 320 of the third plate 300, which functions as a fluid flow path, is located directly over the second region 122b of the first multi-channel capillary region 120. Specifically, the operating fluid, which returns to the evaporation unit 12 through the second hole 320, flows from the second region 122b to the first region 122a through the channels 122 of the first multi-channel capillary region 120 and ends up filling the entire first multi-channel capillary region 120. As described above, since the capillary structure having the stepped region 132 formed on the top surface thereof can prevent vapor from flowing backward, it is unnecessary to install an additional structure for preventing the backward flow of the vapor.

The second multi-channel capillary region 220 of the second plate 200 constituting the condensation unit 14 can condense the operating fluid and includes a plurality of channels 222 to enable the condensed fluid to flow rapidly. The condensed fluid in the second multi-channel capillary region 220 collects in the fluid path 232, which communicates with all the channels 222 on both sides of the second multi-channel capillary region 220, and returns to the evaporation unit 12 through the fluid path 232 and the second hole 320 of the third plate 300.

The inside of the above-described heat uniforming device 10A for the electronic apparatus is made vacuous and filled with the operating fluid through the fluid injection port 240. The operating fluid evaporates due to heat, which is transmitted from the heating source 18 to the evaporation unit 12, so that the heat is changed into latent heat. Vapor evaporated from the evaporation unit 12 is transferred to the condensation unit 14 through the first flow path 22 guided by the first hole 310 of the third plate 300 due to a pressure difference. While emitting heat, the vapor is condensed in the condensation unit 14. A fluid condensed in the condensation unit 12 returns again to the evaporation unit 14 through the second flow path 24 guided by the second hole 320 of the third plate 300. In this process, a loop circulation including the evaporation and condensation of the operating fluid is repeated.

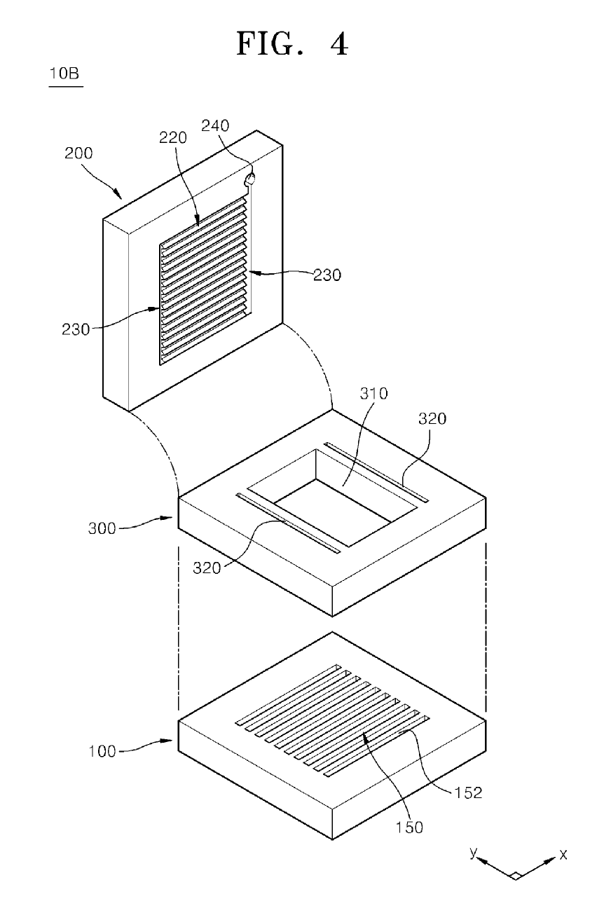

FIG. 4 is an exploded perspective view of an essential part of a heat uniforming device 10B for an electronic apparatus according to another embodiment of the present invention.

The heat uniforming device 10B for the electronic apparatus according to the current embodiment of the present invention as illustrated in FIG. 4 is generally the same as the heat uniforming device 10A for the electronic apparatus as illustrated in FIG. 3A except that a stepped portion 132 is not formed on a top surface of a first multi-channel capillary region 150 formed in a first plate 100. In FIG. 4, the same reference numerals are used to denote the same elements as in FIGS. 3A through 3C, and a detailed description thereof will not be presented here.

The first multi-channel capillary region 150 includes a plurality of groove-type channels 152, which are formed parallel to one another in a predetermined direction, for example, in an x direction as illustrated in FIG. 4.

Although not shown in the drawings, the first multi-channel capillary region 150 may include a mesh-shaped groove comprised of a plurality of first grooves and a plurality of second grooves such that a plurality of channels extend in two directions and intersect one another. The first grooves may be formed parallel to one another in a predetermined first direction, and the second grooves may be formed parallel to one another in a second direction different from the first direction and connected to the first grooves. Here, the first direction may be at right angles to the second direction.

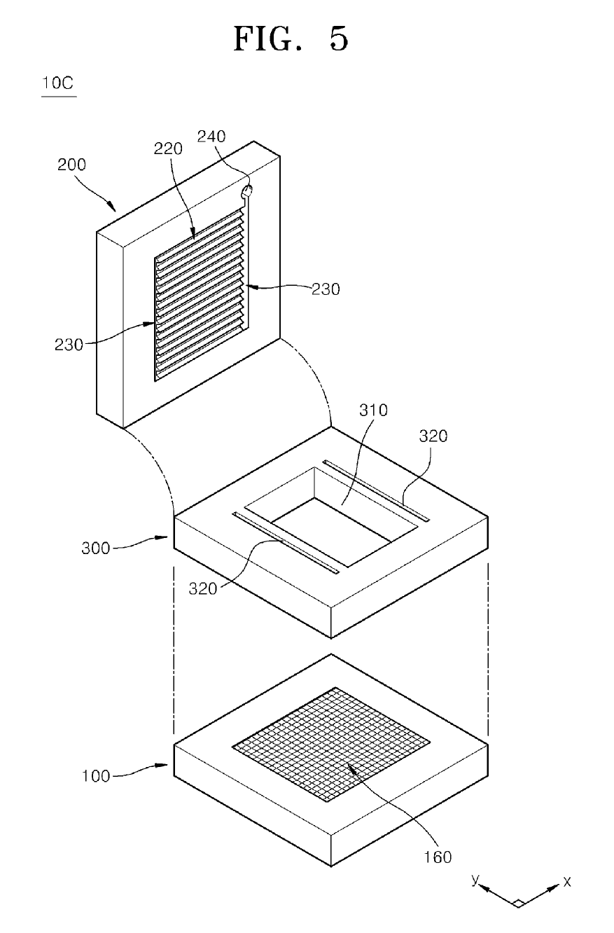

FIG. 5 is an exploded perspective view of an essential part of a heat uniforming device 10C for an electronic apparatus according to yet another embodiment of the present invention.

The heat uniforming device 10C for the electronic apparatus according to the current embodiment of the present invention as illustrated in FIG. 5 is generally the same as the heat uniforming device 10A for the electronic apparatus as illustrated in FIG. 3A except that a first multi-channel capillary region 160 formed in a first plate 100 has a screen mesh structure or a sintered structure. In FIG. 5, the same reference numerals are used to denote the same elements as in FIGS. 3A through 3C, and a detailed description thereof will not be presented here.

For example, a fold of screen mesh or a plurality of folds of screen meshes may be inserted into the first multi-channel capillary region 160.

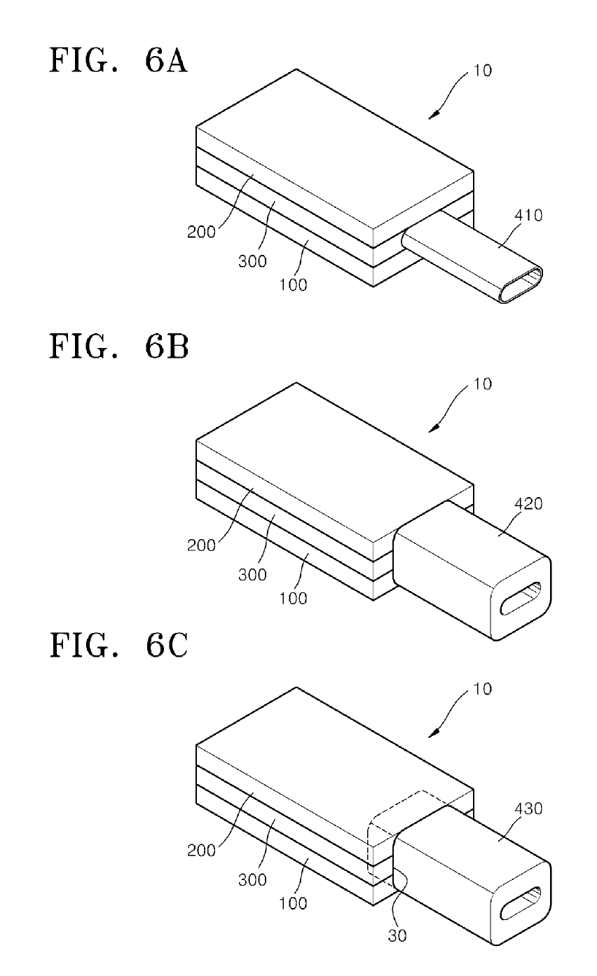

FIGS. 6A through 6C are perspective views of various examples of an operating fluid injection unit that is applicable to a heat uniforming device for an electronic apparatus according to an embodiment of the present invention. FIGS. 6A through 6C respectively illustrate combined structures of operating fluid injection units 410, 420, and 430 installed in the heat uniforming device 10 for the electronic apparatus as illustrated in FIG. 2.

Referring to FIG. 6A, the operating fluid injection unit 410 is installed on a lateral surface of a structure including the first plate 100, the third plate 300, and the second plate 200 that are stacked in sequence and hermetically combined with one another.

In FIG. 6A, the operating fluid injection unit 410 is attached only to an outer wall of the third plate 300 constituting the connection unit 16 among the first through third plates 100, 200, and 300.

Referring to FIG. 6B, the operating fluid injection unit 420 is installed on a lateral surface of a structure including the first plate 100, the third plate 300, and the second plate 200 that are stacked in sequence and hermetically combined with one another. In this case, however, the operating fluid injection unit 420 is attached to outer walls of all the three plates 100, 300, and 200 unlike in FIG. 6A.

Referring to FIG. 6C, the operating fluid 430 is installed on a lateral surface of a structure including the first plate 100, the third plate 300, and the second plate 200 that are stacked in sequence and hermetically combined with one another. Also, the operating fluid injection unit 430 is attached to outer walls of all the three plates 100, 300, and 200 like in FIG. 6B. However, the operating fluid injection unit 430 is inserted to a predetermined length into a recess portion formed in an outer wall of the heat uniforming device 10 for the electronic apparatus.

### INDUSTRIAL APPLICABILITY

A heat uniforming device for an electronic apparatus according to the present invention includes an evaporation unit, which is comprised of a planar first plate including a first multi-channel capillary region for evaporating an operating fluid, and a condensation unit, which is comprised of a planar second plate including a second multi-channel capillary region for condensing vapor supplied from the evaporation unit. The first multi-channel capillary region has a capillary structure having a plurality of channels to improve capillary attraction, so that the operating fluid may be efficiently circulated through evaporation and condensation processes. Also, the multi-channel capillary structure of the first multi-channel capillary region can prevent vapor from flowing backward in the evaporation unit. Thus, it is unnecessary to install an additional component or structure for preventing the backward flow of the vapor. As a result, a relatively wide space for vapor can be ensured.

Furthermore, the heat uniforming device for the electronic apparatus according to the present invention can simply design the thickness and width thereof adaptable to a heating portion of the electronic apparatus and a space where the heat uniforming device will be installed. Therefore, the heat uniforming device for the electronic apparatus according to the present invention can be applied to various fields of electronic apparatuses and, particularly, can be used as a heat dissipation/uniforming device for thin portable electronic apparatuses.

1. A heat uniforming device for an electronic apparatus, the heat uniforming device comprising:
an evaporation unit comprised of a planar first plate including a first multi-channel capillary region for evaporating an externally injected operating fluid due to heat transmitted from a heating source; and
a condensation unit comprised of a planar second plate including a second multi-channel capillary region for condensing vapor supplied from the evaporation unit and a return region having a fluid path that communicates with all channels of the second multi-channel capillary region.

2. The device of claim 1, further comprising a connection unit comprised of a third plate including a first hole forming a first flow path through which the vapor flows from the evaporation unit to the condensation unit, the first hole communicating with the first multi-channel capillary region, and a second hole forming a second flow path through which a fluid returns from the condensation unit to the evaporation unit, the second hole communicating with the fluid path of the return region.

3. The device of claim 1, wherein the first multi-channel capillary region includes a plurality of grooves.

4. The device of claim 3, wherein the grooves include a plurality of first grooves formed parallel to one another in a predetermined first direction.

5. The device of claim 3, wherein the grooves include a plurality of first grooves formed parallel to one another in a predetermined first direction and a plurality of second grooves formed parallel to one another in a second direction different from the first direction and connected to the first grooves, and the first and second grooves form a mesh shape.

6. The device of claim 5, wherein the first grooves are at right angles to the second grooves.

7. The device of claim 3, wherein the first multi-channel capillary region includes at least one stepped portion disposed on a top surface of the first multi-channel capillary region,
and the depth of the grooves is variable in a lengthwise direction of the grooves.

8. The device of claim 1, wherein the first multi-channel capillary region includes at least one fold of screen mesh inserted into the first plate.

9. The device of claim 1, wherein the second multi-channel capillary region includes a plurality of grooves formed parallel to one another in a predetermined direction.

10. The device of claim 9, wherein the fluid path of the return region of the condensation unit extends in a direction perpendicular to a direction in which the grooves of the second multi-channel capillary region extend.

11. The device of claim 2, wherein the first hole of the third plate is interposed between a first region selected out of the first multi-channel capillary region and the second multi-channel capillary region such that the first region of the first multi-channel capillary region communicates with the second multi-channel capillary region.

12. The device of claim 11, wherein the second hole of the third plate is interposed between the fluid path of the return region and a second region selected out of the first multi-channel capillary region such that the fluid path of the return region communicates with the second region of the first multi-channel capillary region.

13. The device of claim 12, wherein the first multi-channel capillary region includes a plurality of grooves, which extend parallel to one another such that the grooves communicate with the first and second regions,
and the grooves are deeper in the second region than in the first region.

14. The device of claim 1, wherein at least one of the first and second multi-channel capillary regions includes a plurality of grooves that extend parallel to one another,
wherein each of the grooves has one selected from the group consisting of a semicircular sectional shape, a semi-elliptical sectional shape, and a polygonal sectional shape.

15. The device of claim 14, wherein the grooves are spaced a predetermined distance apart from one another.

16. The device of claim 14, wherein the grooves are disposed adjacently to one another without leaving any distance from one another.

17. The device of claim 2, wherein the third plate is interposed between the first and second plates,
wherein the first, second, and third plates are hermetically combined with one another to make a flow path of the operating fluid airtight.

18. The device of claim 2, wherein at least one of the first, second, and third plates includes an operating fluid injection unit having a fluid injection hole for externally injecting the operating fluid.

19. The device of claim 18, wherein at least one of the first, second, and third plates includes an operating fluid injection port for externally injecting the operating fluid,
wherein the operating fluid injection port communicates with the fluid injection hole of the operating fluid injection unit.

20. The device of claim 18, wherein the operating fluid injection port is formed in the second plate,
and the operating fluid injection port of the second plate communicates with the fluid path of the return region.
